(19) United States
(12) Patent Application Publication
(10) Pub. No.: US 2026/0310319 A1
(43) Pub. Date: Oct. 8, 2026

(54) DISPLAY DEVICE AND ELECTRONIC DEVICE INCLUDING THE SAME

(71) Applicant: Samsung Display Co., Ltd., Yongin-si (KR)

(72) Inventors: Minha HWANG, Yongin-si (KR); Deokhoi KIM, Yongin-si (KR)

(73) Assignee: Samsung Display Co., Ltd., Yongin-si (KR)

(21) Appl. No.: 19/391,319

(22) Filed: Nov. 17, 2025

(30) Foreign Application Priority Data
Apr. 8, 2025 (KR) 10-2025-0045213

(51) Int. Cl. G06F 3/041; G06F 3/044

(52) U.S. Cl. CPC G06F 3/0418; G06F 3/0445; G06F 3/0446; G06F 2203/04107; G06F 2203/04112

(57) ABSTRACT

A display device may include a substrate, a light-emitting element layer on the substrate and including a light-emitting element, an encapsulation layer on the light-emitting element layer and covering the light-emitting element, a sensing electrode on the encapsulation layer, a sensing line on the encapsulation layer and including a first end connected to the sensing electrode, a first noise reduction pattern between the encapsulation layer and the sensing line, overlapping or within a predetermined distance from the first end in a plan view, and configured to reduce noise applied to the sensing line, and a second noise reduction pattern on the sensing line, overlapping or within the predetermined distance from the first end in the plan view, configured to reduce the noise applied to the sensing line, and connected to the first noise reduction pattern.

### CROSS-REFERENCE TO RELATED APPLICATION

This application claims priority under 35 USC § 119 to Korean Patent Application No. 10-2025-0045213, filed on Apr. 08, 2025, in the Korean Intellectual Property Office, the content of which is herein incorporated by reference in its entirety.

### BACKGROUND

The present disclosure relates generally to a display device. More particularly, the present disclosure relates to a display device and an electronic device including the display device.

With the development of information technology, the importance of a display device, which services as an interface between users and information, has been highlighted. For example, the use of display devices such as liquid crystal display (LCD) device, organic light emitting diode (OLED) display device, plasma display panel (PDP) device, quantum dot display device or the like is increasing.

The display device may include a display panel that displays an image and an input sensing panel that is disposed on the display panel and senses an external input. The input sensing panel may sense an external input, such as a user’s touch. When the input sensing panel senses the external input, an input signal may be generated. The input signal may be provided to the display panel, and the display panel may provide an image corresponding to the input signal to the user.

### SUMMARY

Embodiments provide a display device including a input sensing panel with improved reliability.

Embodiments provide an electronic device including the display device.

According to an aspect of the disclosure, a display device may include: a substrate; a light-emitting element layer on the substrate and including a light-emitting element; an encapsulation layer on the light-emitting element layer and covering the light-emitting element; a sensing electrode on the encapsulation layer; a sensing line on the encapsulation layer and including a first end connected to the sensing electrode; a first noise reduction pattern between the encapsulation layer and the sensing line, overlapping or within a predetermined distance from the first end in a plan view, and configured to reduce noise applied to the sensing line; and a second noise reduction pattern on the sensing line, overlapping or within the predetermined distance from the first end in the plan view, configured to reduce the noise applied to the sensing line, and connected to the first noise reduction pattern.

According to an aspect of the disclosure, a display device may include: a substrate; a light-emitting element layer on the substrate and including a light-emitting element; an encapsulation layer on the light-emitting element layer and covering the light-emitting element; a sensing electrode on the encapsulation layer; a first noise reduction member on the encapsulation layer and including a magnetic material; and a sensing line on the encapsulation layer, the sensing line including a first end connected to the sensing electrode, having a coil shape, and surrounding the first noise reduction member at the first end.

According to an aspect of the disclosure, an electronic device may include: a display panel including a substrate, a light-emitting element on the substrate, and an encapsulation layer on the light-emitting element and covering the light-emitting element; an input sensing panel on the display panel; and a processor configured to transmit an image data signal and an input control signal to the display panel. The input sensing panel may include: a sensing electrode on the encapsulation layer; a sensing line on the encapsulation layer and including a first end connected to the sensing electrode; a first noise reduction pattern between the encapsulation layer and the sensing line, overlapping or within a predetermined distance from the first end in a plan view, and configured to reduce noise applied to the sensing line; and a second noise reduction pattern on the sensing line, overlapping or within the predetermined distance from the first end in the plan view, configured to reduce the noise applied to the sensing line, and connected to the first noise reduction pattern.

### BRIEF DESCRIPTION OF DRAWINGS

Illustrative, non-limiting embodiments will be more clearly understood from the following detailed description in conjunction with the accompanying drawings.

FIG. 1 is a block diagram illustrating a display device according to an embodiment of the present disclosure.

FIG. 2 is a plan view illustrating the display device of FIG. 1.

FIG. 3 is a cross-sectional view illustrating the display device of FIG. 1.

FIG. 4 is a cross-sectional view illustrating a display module included in the display device of FIG. 3.

FIG. 5 is a plan view illustrating an example of an input sensing panel included in the display device of FIG. 3.

FIG. 6 is an enlarged plan view of the area A of FIG. 5.

FIG. 7 is a cross-sectional view taken along the line I-I` of FIG. 6.

FIG. 8 is a plan view illustrating a sensing line and a noise reduction member included in the input sensing panel of FIG. 5.

FIG. 9 is a cross-sectional view taken along the line II-II` of FIG. 8.

FIG. 10 is a plan view illustrating another example of an input sensing panel included in the display device of FIG. 3.

FIG. 11 is a plan view illustrating a sensing line and a noise reduction member included in the input sensing panel of FIG. 10.

FIG. 12 is a block diagram illustrating an electronic device according to an embodiment of the present disclosure.

FIG. 13 is a schematic view of an electronic device according to various embodiments.

### DETAILED DESCRIPTION

Example embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the example embodiments. However, it is apparent that the example embodiments can be practiced without those specifically defined matters. Also, well-known functions or constructions are not described in detail since they would obscure the description with unnecessary detail.

In the present disclosure, the term “an embodiment” is intended to encompass one or more embodiments, rather than being limited to a single example. Furthermore, features described in embodiments may be combined and implemented together.

Expressions such as "at least one of," when preceding a list of elements, modify the entire list of elements and do not modify the individual elements of the list. For example, the expression, "at least one of a, b, and c," should be understood as including only a, only b, only c, both a and b, both a and c, both b and c, all of a, b, and c, or any variations of the aforementioned examples.

While such terms as “first,” “second,” etc., may be used to describe various elements, such elements must not be limited to the above terms. The above terms may be used only to distinguish one element from another.

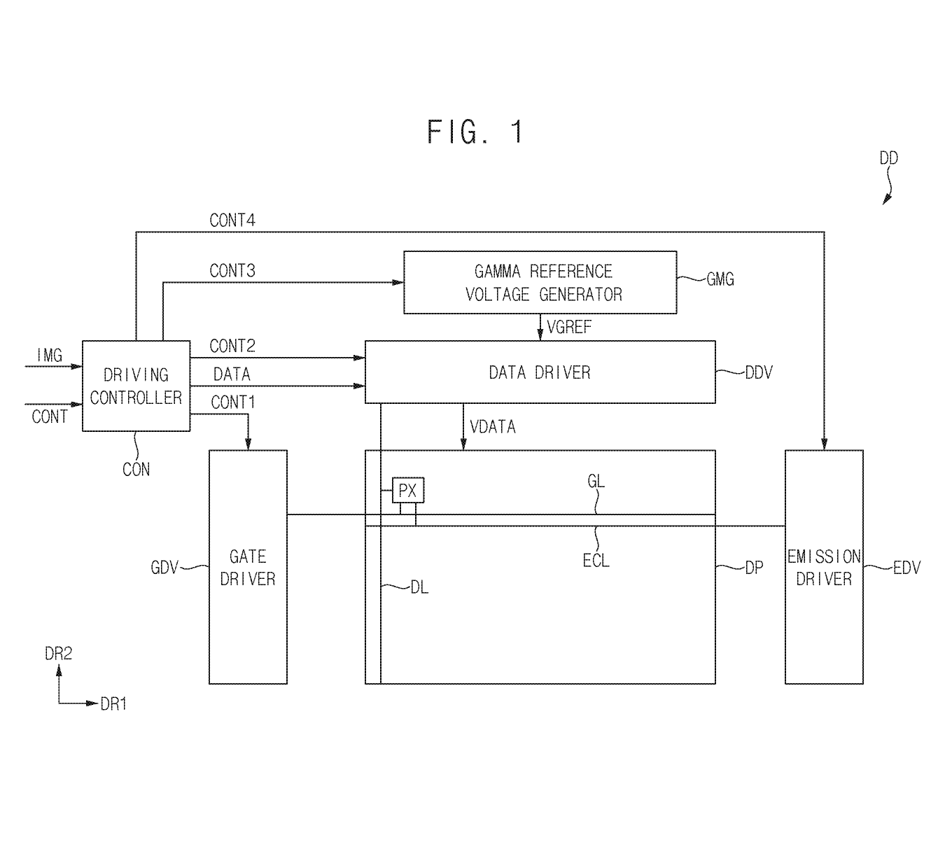

FIG. 1 is a block diagram illustrating a display device according to an embodiment of the present disclosure.

Referring to FIG. 1, a display device DD according to an embodiment of the present disclosure may include a display panel DP and a panel driver that drives the display panel DP. The panel driver may include a driving controller CON, a gate driver GDV, a gamma reference voltage generator GMG, a data driver DDV, and an emission driver EDV.

For example, the driving controller CON and the data driver DDV may be integrally formed as a single module. A driving module in which the driving controller CON and the data driver DDV are integrally formed may be referred to as a timing controller embedded data driver (TED).

The display panel DP may include gate lines GL, emission lines ECL, data lines DL, and pixels PX. The pixels PX may be electrically connected to the gate lines GL, the emission lines ECL, and the data lines DL. Each of the pixels PX may generate and emit light in response to a driving signal. For example, each of the gate lines GL may extend in a first direction DR1, and each of the emission lines ECL may extend in the first direction DR1. Each of the data lines DL may extend in a second direction DR2 intersecting the first direction DR1. For example, the first direction DR1 and the second direction DR2 may be perpendicular to each other.

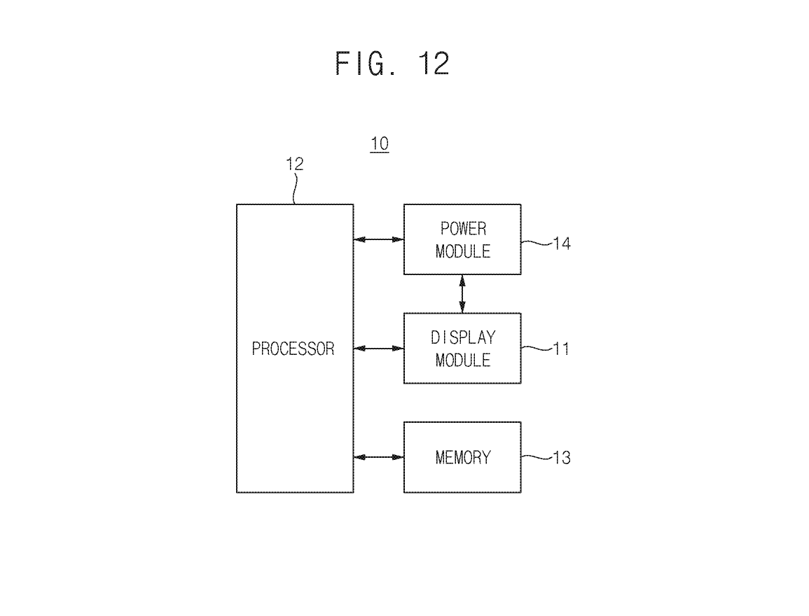

The driving controller CON may receive an image data signal IMG and an input control signal CONT from an external device (e.g., a processor 12 of FIG. 12). For example, the image data signal IMG may include red image data, green image data, and blue image data. In an embodiment, the image data signal IMG may further include white image data. The input control signal CONT may include a vertical synchronization signal, a horizontal synchronization signal, a data enable signal, a master clock signal, or the like.

The driving controller CON may generate a first control signal CONT1, a second control signal CONT2, a third control signal CONT3, a fourth control signal CONT4, and a data signal DATA based on the image data signal IMG and the input control signal CONT.

The driving controller CON may output the first control signal CONT1 to the gate driver GDV. The first control signal CONT1 may include a vertical start signal and a gate clock signal. The driving controller CON may output the second control signal CONT2 and the data signal DATA to the data driver DDV. The second control signal CONT2 may include a horizontal start signal and a load signal. The driving controller CON may output a third control signal CONT3 to the gamma reference voltage generator GMG. The driving controller CON may output the fourth control signal CONT4 to the emission driver EDV.

The gate driver GDV may generate gate signals in response to the first control signal CONT1. The gate driver GDV may output the gate signals to the gate lines GL.

The gamma reference voltage generator GMG may generate the gamma reference voltage VGREF in response to the third control signal CONT3. The gamma reference voltage generator GMG may provide a gamma reference voltage VGREF to the data driver DDV. For example, the gamma reference voltage generator GMG may be disposed in or integrated within the driving controller CON, or may be disposed in or integrated within the data driver DDV.

The data driver DDV may receive the second control signal CONT2 and the data signal DATA from the driving controller CON, and may receive the gamma reference voltage VGREF from the gamma reference voltage generator GMG. The data driver DDV may convert the data signal DATA into an analog form of a data voltage VDATA based on the gamma reference voltage VGREF. The data driver DDV may output the data voltage VDATA to the data lines DL.

The emission driver EDV may generate emission control signals in response to the fourth control signal CONT4. The emission driver EDV may output the emission control signals to the emission lines ECL.

In FIG. 1, for convenience of description, the gate driver GDV is shown positioned on a first side of the display panel DP, while the emission driver EDV is shown on a second side opposite to the first side of the display panel DP. However, embodiments of the present disclosure are not limited to this configuration. For example, both the gate driver GDV and the emission driver EDV may be positioned on the first side of the display panel DP. For another example, both the gate driver GDV and the emission driver EDV may be positioned on opposite sides of the display panel DP. For still another example, the gate driver GDV and the emission driver EDV may be integrally formed as a single module.

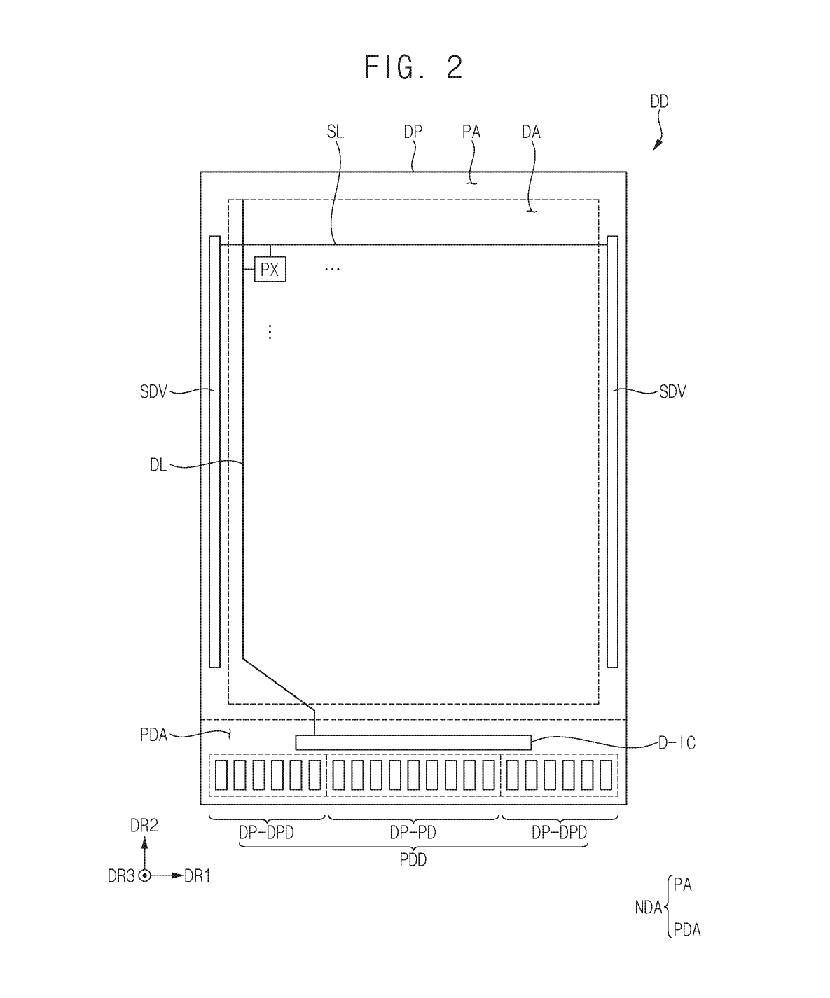

FIG. 2 is a plan view illustrating the display device of FIG. 1.

In the present disclosure, a plane may be defined by the first direction DR1 and the second direction DR2, and a direction normal to the plane may be a third direction DR3. In other words, the third direction DR3 may be perpendicular to each of the first direction DR1 and the second direction DR2. The third direction DR3 may be a thickness direction of the display device DD. As used herein the “plan view” is a view in the third direction DR3.

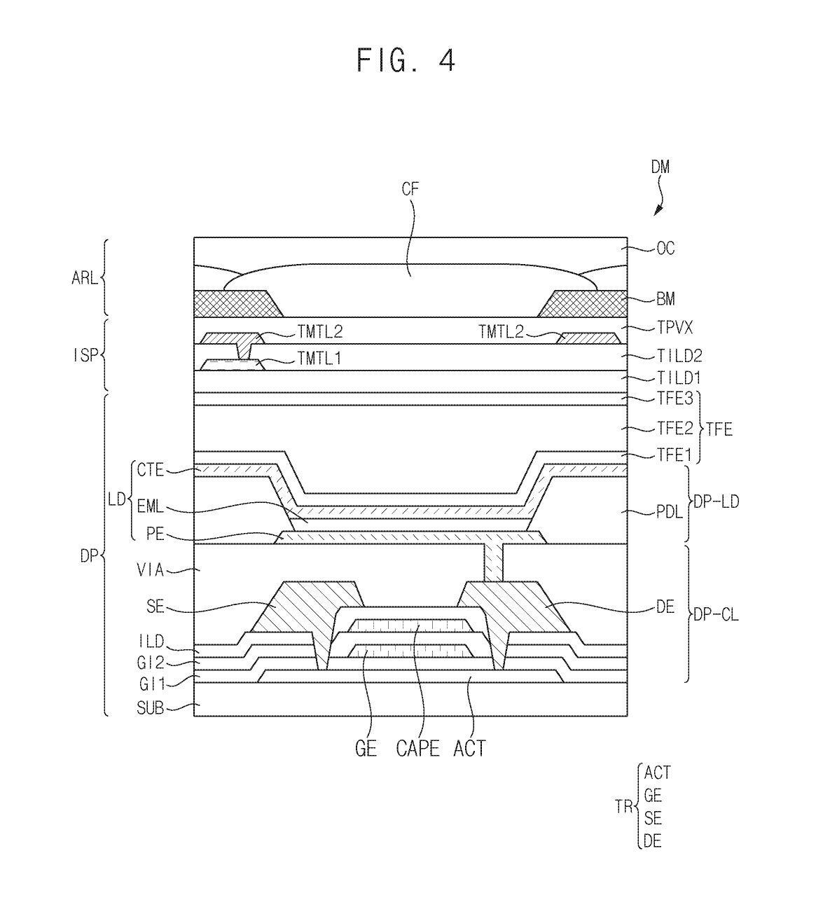

Referring to FIG. 2, the display device DD may include the display panel DP, a scan driver SDV, and a driving chip D-IC. The display panel DP may include a substrate (SUB, see FIG. 4), the pixels PX, scan lines SL, the data lines DL, and a pad portion PDD.

The display panel DP may include a display area DA and a non-display area NDA. The display area DA may be an area that displays an image by generating light or adjusting the transmittance of light provided by an external light source. The non-display area NDA may be positioned around the display area DA. The non-display area NDA may be an area that does not display an image. The non-display area NDA may include a peripheral area PA and a pad area PDA.

The peripheral area PA may surround at least a portion of the display area DA in a plan view. For example, the peripheral area PA may entirely surround the display area DA in a plan view.

The pad area PDA may be positioned on a side of the display area DA. For example, the pad area PDA may be disposed on a lower side of the display area DA, but the present disclosure is not necessarily limited thereto. The pad area PDA may be spaced apart from the display area DA by the peripheral area PA in a plan view. For example, the pad area PDA and the display area DA may be spaced apart from each other in the second direction DR2.

The substrate may form a base of the display device DD. The substrate may include a transparent material or an opaque material. Examples of materials that may be used as the substrate may include glass, quartz, silicon, polymer, or the like. These materials may be used alone or in combination with each other. As the display panel DP includes the display area DA, the peripheral area PA, and the pad area PDA, the substrate may also include the display area DA, the peripheral area PA, and the pad area PDA.

The pixels PX may be disposed in the display area DA on the substrate. The pixels PX may be electrically connected to the scan line SL and the data line DL. In this case, the scan line SL may correspond to the gate line GL or the emission line ECL of FIG. 1. For example, the pixels PX may be arranged in a matrix form along the first direction DR1 and the second direction DR2.

The scan driver SDV may be disposed in the peripheral area PA on the substrate. In an embodiment, the scan driver SDV may be disposed on opposite sides of the display area DA in the first direction DR1. However, the present disclosure is not necessarily limited thereto. The scan driver SDV may correspond to the gate driver GDV or the emission driver EDV of FIG. 1. For example, the scan driver SDV may output the gate signal to the scan line SL. The gate signal may be applied to the pixels PX through the scan line SL. For example, the scan driver SDV may output the emission control signal to the scan line SL. The emission control signal may be applied to the pixels PX through the scan line SL.

The pad portion PDD may be disposed in the pad area PDA on the substrate. For example, the pad portion PDD may be adjacent to the lower side of the display area DA. The pad portion PDD may include signal pads DP-PD and dummy pads DP-DPD.

The signal pads DP-PD may be connected to the pixels PX through transmission lines, respectively. In addition, at least some of the signal pads DP-PD may be connected to the driving chip D-IC. The signal pads DP-PD may transmit a driving signal to the pixels PX. The driving signal may include various signals for driving the pixels PX, such as a driving voltage, a control signal, or the like.

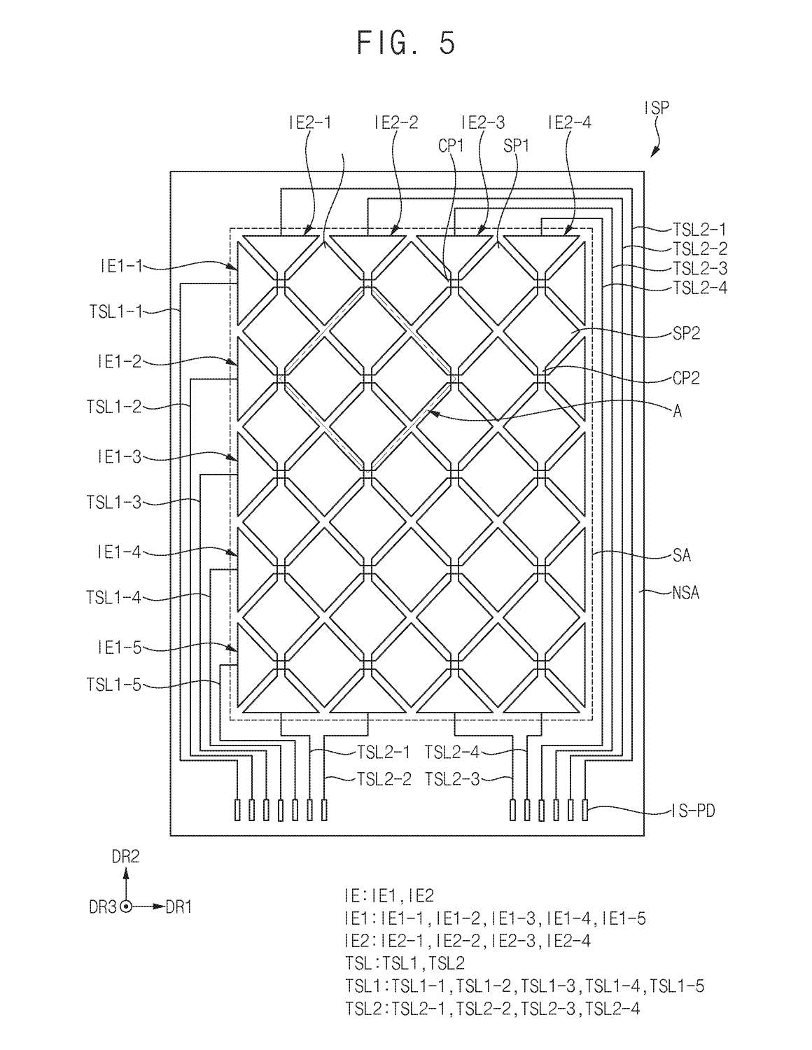

The dummy pads DP-DPD may be optionally provided in the display device DD including an input sensing panel (ISP, see FIG. 5). The dummy pads DP-DPD may overlap the sensing pads IS-PD of the input sensing panel ISP of FIG. 5 described below. The dummy pads DP-DPD may be adjacent to the signal pads DP-PD. For example, the dummy pads DP-DPD may be disposed on opposite sides of the signal pads DP-PD, but the present disclosure is not necessarily limited thereto.

The driving chip D-IC may be disposed in the pad area PDA on the substrate. For example, the driving chip D-IC may be adjacent to the lower side of the display area DA. The driving chip D-IC may correspond to the data driver DDV of FIG. 1. That is, the driving chip D-IC may output the data voltage (VDATA, see FIG. 1) to the data line DL. The data voltage may be applied to the pixels PX through the data line DL.

In an embodiment, the driving chip D-IC may be mounted on the substrate. However, the present disclosure is not necessarily limited thereto, and the driving chip D-IC may be disposed on a circuit board bonded to the substrate in the form of a chip on film (COF).

A circuit board may be disposed in the pad area PDA on the substrate. The circuit board may overlap the pad portion PDD in a plan view. The circuit board may be connected to the pad portion PDD through an anisotropic conductive film (ACF). For example, the circuit board may be a flexible printed circuit board (FPCB).

In FIG. 2, the display device DD is illustrated as having a rectangular planar shape having a short side extending in the first direction DR1 and a long side extending in the second direction DR2, but the present disclosure is not necessarily limited thereto. The planar shape of the display device DD may be variously changed according to embodiments.

In addition, the number or arrangement relationship of the driving chip D-IC and the number or arrangement relationship of the scan driver SDV illustrated in FIG. 2 are merely examples, and the present disclosure is not necessarily limited thereto.

In an embodiment, the display device DD may be a small display device used in a small electronic device such as a smartphone, a cell phone, a smart watch, a gaming console, and a camera. However, the present disclosure is not necessarily limited thereto, and the display device DD may be a medium- to large-sized display device used in a medium- to large-sized electronic device, such as a laptop, a tablet PC, a television, a computer monitor, an in-vehicle monitor, and an exterior billboards.

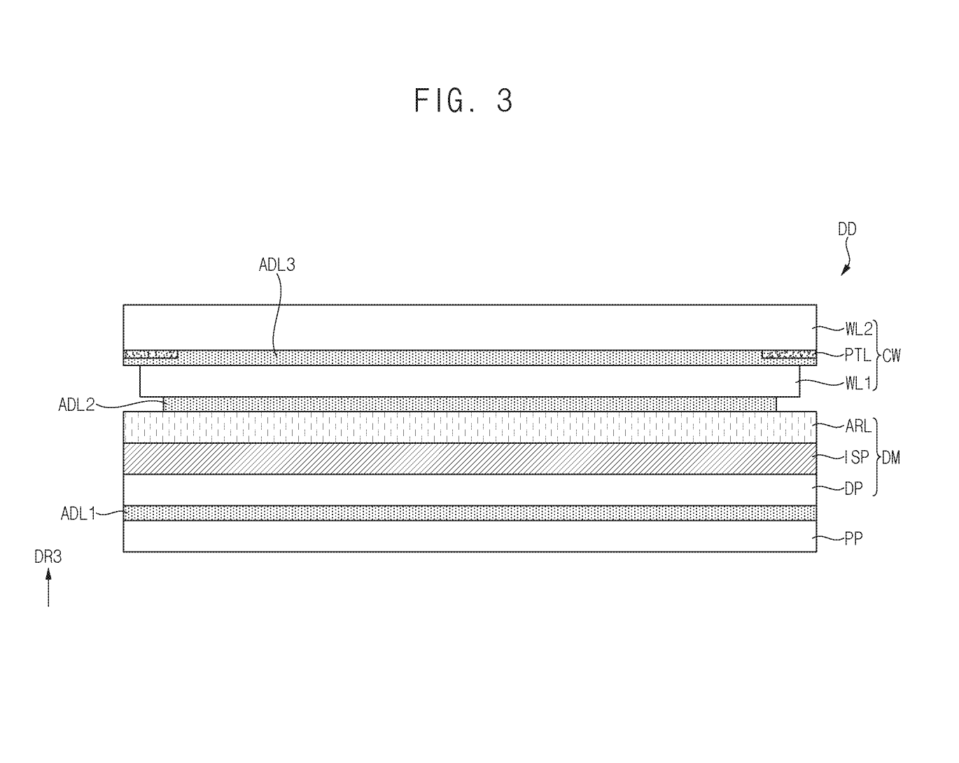

FIG. 3 is a cross-sectional view illustrating the display device of FIG. 1.

Referring to FIG. 3, the display device DD may include a display module DM, a cover window CW, a protective panel PP, and first to third adhesive layers ADL1, ADL2, and ADL3. The display module DM may include the display panel DP, an input sensing panel ISP, and an anti-reflection layer ARL.

The protective panel PP may be disposed under the display module DM. The protective panel PP may be attached to the display module DM through the first adhesive layer ADL1. For example, the protective panel PP may be attached to a lower surface of the display panel DP through the first adhesive layer ADL1. The protective panel PP may protect the display module DM from external impact. The protective panel PP may include an organic material having flexibility. For example, the protective panel PP may include polyethylene terephthalate (PET), polyimide (PI), polyethylene naphthalate (PEN), or the like. These materials may be used alone or in combination with each other.

The first adhesive layer ADL1 may be disposed between the display module DM and the protective panel PP. For example, the first adhesive layer ADL1 may be disposed between the display panel DP and the protective panel PP. The first adhesive layer ADL1 may attach the display module DM to the protective panel PP.

The input sensing panel ISP may be disposed on the display panel DP. In an embodiment, the input sensing panel ISP may be directly disposed on the display panel DP. In this specification, “component A is directly disposed on component B” means that no adhesive layer is disposed between component A and component B. That is, the input sensing panel ISP may be formed through a continuous process with the display panel DP, and may be directly disposed on the display panel DP without an adhesive layer. However, the present disclosure is not necessarily limited thereto, and the input sensing panel ISP may be provided as an individual panel and attached to an upper surface of the display panel DP through an adhesive layer.

The input sensing panel ISP may obtain coordinate information according to an external input. The external input may be provided in various forms. For example, the external input may be in the form of a user’s touch, a pen touch, light, heat, pressure, or the like. In addition, the external input may be in the form of an input by direct contact or a touch of an adjacent space (e.g., hovering). For example, the input sensing panel ISP may acquire coordinate information based on the external input, such as the user’s touch. For example, the input sensing panel ISP may acquire coordinate information based on the external input using a mutual capacitance method and/or a self-capacitance method. The input sensing panel ISP may include a plurality of sensing electrodes, sensing lines connected to corresponding sensing electrodes, and at least one sensing insulating layer. A detailed description thereof will be described below with reference to FIGS. 4 and 5.

The anti-reflection layer ARL may be disposed on the display panel DP. For example, the anti-reflection layer ARL may be disposed on the input sensing panel ISP. In an embodiment, the anti-reflection layer ARL may be directly disposed on the input sensing panel ISP. That is, the anti-reflection layer ARL may be formed through a continuous process with the display panel DP and the input sensing panel ISP, and may be directly disposed on the input sensing panel ISP without an adhesive layer. However, the present disclosure is not necessarily limited thereto, and the anti-reflection layer ARL may be attached to an upper surface of the input sensing panel ISP through an adhesive layer.

The anti-reflection layer ARL may reduce external light reflection of the display device DD. That is, the anti-reflection layer ARL may be disposed on the display panel DP and may reduce the reflectivity of external light incident toward the display panel DP. As the reflectivity of the external light is reduced, the visibility of the display device DD may be improved. In an embodiment, the anti-reflection layer ARL may include color filters (CF, see FIG. 4) and a light blocking pattern (BM, see FIG. 4) disposed between the color filters CF. A detailed description thereof will be described below with reference to FIG. 4. However, the present disclosure is not necessarily limited thereto, and the anti-reflection layer ARL may include a polarizer of a stretched film type.

The cover window CW may be disposed on the display module DM. The cover window CW may be attached to the display module DM through the second adhesive layer ADL2. For example, the cover window CW may be attached to an upper surface of the anti-reflection layer ARL through the second adhesive layer ADL2. The cover window CW may cover and protect the display module DM. For example, the cover window CW may protect the display module DM from external scratches. The cover window CW may include a window substrate WL1, a window protective layer WL2, and a printing layer PTL.

The second adhesive layer ADL2 may be disposed between the display module DM and the cover window CW. For example, the second adhesive layer ADL2 may be disposed between the anti-reflection layer ARL and the window substrate WL1. The second adhesive layer ADL2 may attach the display module DM and the cover window CW.

The window substrate WL1 may include a transparent material. For example, the window substrate WL1 may include glass, quartz, polymers, or the like. These materials may be used alone or in combination with each other.

The window protective layer WL2 may be disposed on the window substrate WL1. The window protective layer WL2 may be attached to an upper surface of the window substrate WL1 through the third adhesive layer ADL3. The window protective layer WL2 may have a thickness (e.g., a length in the third direction DR3) relatively greater than a thickness of the window substrate WL1. The window protective layer WL2 may protect the window substrate WL1. The window protective layer WL2 may include a material having a modulus relatively lower than a modulus of the window substrate WL1. In an embodiment, the window protective layer WL2 may further include an anti-fingerprint functional layer.

The third adhesive layer ADL3 may be disposed between the window substrate WL1 and the window protective layer WL2. The third adhesive layer ADL3 may attach the window substrate WL1 to the window protective layer WL2.

For example, each of the first to third adhesive layers ADL1, ADL2, and ADL3 may include a pressure sensitive adhesive (PSA) film, an optically clear adhesive (OCA) film, or an optically clear resin (OCR).

The printing layer PTL may be disposed between the window substrate WL1 and the window protective layer WL2. For example, the printing layer PTL may be disposed on a lower surface of the window protective layer WL2. The printing layer PTL may be adjacent to an edge of the window protective layer WL2. The printing layer PTL may overlap the non-display area NDA of FIG. 2. The printing layer PTL may include a light blocking material. For example, the light blocking material may be a black pigment, a black dye, carbon black, or the like. These materials may be used alone or in combination with each other.

FIG. 4 is a cross-sectional view illustrating a display module included in the display device of FIG. 3.

Referring to FIG. 4, the display module DM may include the display panel DP, the input sensing panel ISP disposed on the display panel DP, and the anti-reflection layer ARL disposed on the input sensing panel ISP. The display panel DP may include a substrate SUB, a circuit element layer DP-CL, a light-emitting element layer DP-LD, and an encapsulation layer TFE. The input sensing panel ISP may include a first sensing insulating layer TILD1, a first sensing conductive pattern TMTL1, a second sensing insulating layer TILD2, a second sensing conductive pattern TMTL2, and a sensing protective layer TPVX. The anti-reflection layer ARL may include a color filter CF, a light blocking pattern BM, and a flattening layer OC.

The circuit element layer DP-CL may include a transistor TR, a first gate insulating layer GI1, a second gate insulating layer GI2, a capacitor electrode CAPE, an inter-layer insulating layer ILD, and a via-insulating layer VIA. The transistor TR may include an active pattern ACT, a gate electrode GE, a source electrode SE, and a drain electrode DE.

The light-emitting element layer DP-LD may include a light-emitting element LD and a pixel defining layer PDL. The light-emitting element LD may include a pixel electrode PE, a light-emitting layer EML, and a common electrode CTE.

The active pattern ACT may be disposed on the substrate SUB. The active pattern ACT may include a silicon semiconductor, an oxide semiconductor, an organic semiconductor, or the like. The active pattern ACT may include a source area, a drain area, and a channel area between the source area and the drain area.

The first gate insulating layer GI1 may be disposed on the substrate SUB. The first gate insulating layer GI1 may cover the active pattern ACT. The first gate insulating layer GI1 may include an inorganic insulating material. Examples of the inorganic insulating material may include silicon oxide (SiOₓ), silicon nitride (SiNₓ), silicon oxynitride (SiOₓN_{y}), or the like. These materials may be used alone or in combination with each other.

The gate electrode GE may be disposed on the first gate insulating layer GI1. The gate electrode GE may overlap the channel area of the active pattern ACT in a plan view. The gate electrode GE may include a conductive material such as a metal, an alloy, a conductive metal nitride, a conductive metal oxide, a transparent conductive oxide, or the like. Examples of the conductive material that may be used as the gate electrode GE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These materials may be used alone or in combination with each other.

The second gate insulating layer GI2 may be disposed on the first gate insulating layer GI1. The second gate insulating layer GI2 may cover the gate electrode GE. The second gate insulating layer GI2 may include an inorganic insulating material.

The capacitor electrode CAPE may be disposed on the second gate insulating layer GI2. The capacitor electrode CAPE may overlap the gate electrode GE in a plan view. The capacitor electrode CAPE may include a conductive material such as a metal, an alloy, a conductive metal nitride, a conductive metal oxide, a transparent conductive oxide, or the like.

The inter-layer insulating layer ILD may be disposed on the second gate insulating layer GI2. The inter-layer insulating layer ILD may cover the capacitor electrode CAPE. The inter-layer insulating layer ILD may include an inorganic insulating material.

The source electrode SE and the drain electrode DE may be disposed on the inter-layer insulating layer ILD. The source electrode SE may be connected to the source area of the active pattern ACT through a contact hole penetrating the first gate insulating layer GI1, the second gate insulating layer GI2, and the inter-layer insulating layer ILD. The drain electrode DE may be connected to the drain area of the active pattern ACT through a contact hole penetrating the first gate insulating layer GI1, the second gate insulating layer GI2, and the inter-layer insulating layer ILD. Each of the source electrode SE and the drain electrode DE may include a conductive material such as a metal, an alloy, a conductive metal nitride, a conductive metal oxide, a transparent conductive oxide, or the like.

Accordingly, the transistor TR including the active pattern ACT, the gate electrode GE, the source electrode SE, and the drain electrode DE may be disposed on the substrate SUB.

The via-insulating layer VIA may be disposed on the inter-layer insulating layer ILD. The via-insulating layer VIA may cover the source electrode SE and the drain electrode DE. The via-insulating layer VIA may include an organic insulating material. Examples of the organic insulating material may include a photoresist, a polyacryl-based resin, a polyimide-based resin, a polyamide-based resin, a siloxane-based resin, an acrylic-based resin, an epoxy-based resin, or the like. These materials may be used alone or in combination with each other.

The pixel electrode PE may be disposed on the via-insulating layer VIA. The pixel electrode PE may be connected to the source electrode SE or the drain electrode DE through a contact hole penetrating the via-insulating layer VIA. Accordingly, the pixel electrode PE may be electrically connected to the transistor TR. The pixel electrode PE may include a conductive material such as a metal, an alloy, a conductive metal nitride, a conductive metal oxide, a transparent conductive oxide, or the like. For example, the pixel electrode PE may function as an anode of the light-emitting element LD.

The pixel defining layer PDL may be disposed on the via-insulating layer VIA. The pixel defining layer PDL may cover an edge of the pixel electrode PE and define a pixel opening exposing an upper surface of the pixel electrode PE. The pixel defining layer PDL may include an organic insulating material. In an embodiment, the pixel defining layer PDL may further include an inorganic material or an organic material including a light blocking material having a black color.

The light-emitting layer EML may be disposed on the pixel electrode PE in the pixel opening. The light-emitting layer EML may emit light having a specific color (e.g., red, green, or blue). In an embodiment, the light-emitting layer EML may include at least one of an organic light-emitting material and a quantum dot. For example, the light-emitting layer EML may have a single-layer structure including one light-emitting structure. However, the present disclosure is not necessarily limited thereto, and the light-emitting layer EML may have a tandem structure including a plurality of light-emitting structures.

The common electrode CTE may be disposed on the pixel defining layer PDL and the light-emitting layer EML. The common electrode CTE may cover the pixel defining layer PDL and the light-emitting layer EML, and may be disposed along the profiles of the pixel defining layer PDL and the light-emitting layer EML with a substantially uniform thickness. The common electrode CTE may include a conductive material such as a metal, an alloy, a conductive metal nitride, a conductive metal oxide, a transparent conductive oxide, or the like. For example, the common electrode CTE may function as a cathode of the light-emitting element LD.

Accordingly, the light-emitting element LD including the pixel electrode PE, the light-emitting layer EML, and the common electrode CTE may be disposed on the via-insulating layer VIA.

The encapsulation layer TFE may be disposed on the common electrode CTE. The encapsulation layer TFE may prevent impurities, moisture, or the like from penetrating into the light emitting element LD from the outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), etc. These materials may be used alone or in combination with each other. For example, the organic encapsulation layer may include a polymer cured material such as polyacrylate. In an embodiment, the encapsulation layer TFE may include a first inorganic encapsulation layer TFE1, an organic encapsulation layer TFE2 disposed on the first inorganic encapsulation layer TFE1, and a second inorganic encapsulation layer TFE3 disposed on the organic encapsulation layer TFE2.

The first inorganic encapsulation layer TFE1 and the second inorganic encapsulation layer TFE3 may prevent the light-emitting element LD from being deteriorated due to penetration of moisture, oxygen, or the like. In addition, the first inorganic encapsulation layer TFE1 and the second inorganic encapsulation layer TFE3 may protect the light-emitting element LD from external impact. For example, each of the first inorganic encapsulation layer TFE1 and the second inorganic encapsulation layer TFE3 may include an inorganic material having a flexibility.

The organic encapsulation layer TFE2 may protect the light-emitting element LD from external impact. In addition, the organic encapsulation layer TFE2 may alleviate a step difference of the first inorganic encapsulation layer TFE1. For example, the organic encapsulation layer TFE2 may include an organic material having flexibility.

As described above, the input sensing panel ISP may be directly disposed on the display panel DP. For example, the first sensing insulating layer TILD1 may be directly disposed on the encapsulation layer TFE (e.g., the second inorganic encapsulation layer TFE3). The first sensing insulating layer TILD1 may include an inorganic insulating material and/or an organic insulating material.

The first sensing conductive pattern TMTL1 may be disposed on the first sensing insulating layer TILD1. The first sensing conductive pattern TMTL1 may be disposed in a non-emission area where light is not emitted to the outside. That is, the first sensing conductive pattern TMTL1 may overlap the pixel defining layer PDL in a plan view. In an embodiment, the first sensing conductive pattern TMTL1 may be spaced apart from the light-emitting layer EML in a plan view. For example, the first sensing conductive pattern TMTL1 may have a mesh shape in a plan view. The first sensing conductive pattern TMTL1 may include a conductive material such as a metal, an alloy, a conductive metal nitride, a conductive metal oxide, a transparent conductive oxide, or the like.

The second sensing insulating layer TILD2 may be disposed on the first sensing insulating layer TILD1. The second sensing insulating layer TILD2 may cover the first sensing conductive pattern TMTL1. The second sensing insulating layer TILD2 may include an inorganic insulating material and/or an organic insulating material.

The second sensing conductive pattern TMTL2 may be disposed on the second sensing insulating layer TILD2. The second sensing conductive pattern TMTL2 may be disposed in the non-emission area where light is not emitted. That is, the second sensing conductive pattern TMTL2 may overlap the pixel defining layer PDL in a plan view. In an embodiment, the second sensing conductive pattern TMTL2 may be spaced apart from the light-emitting layer EML in a plan view.

A portion of the second sensing conductive pattern TMTL2 may be connected to the first sensing conductive pattern TMTL1 through a contact hole penetrating the second sensing insulating layer TILD2. For example, the second sensing conductive pattern TMTL2 may have a mesh shape in a plan view. The second sensing conductive pattern TMTL2 may include a conductive material such as a metal, an alloy, a conductive metal nitride, a conductive metal oxide, a transparent conductive oxide, or the like.

The sensing protective layer TPVX may be disposed on the second sensing insulating layer TILD2. The sensing protective layer TPVX may cover the second sensing conductive pattern TMTL2. The sensing protective layer TPVX may include an inorganic insulating material and/or an organic insulating material.

As described above, the anti-reflection layer ARL may be directly disposed on the input sensing panel ISP. For example, the color filter CF and the light blocking pattern BM may be directly disposed on the sensing protective layer TPVX. The color filter CF and the light blocking pattern BM may reduce external light reflection. As the anti-reflection layer ARL includes the color filter CF and the light blocking pattern BM, the display device DD may not include a polarization layer.

The light blocking pattern BM may partition an emission area where light is emitted to the outside. That is, the light blocking pattern BM may define an opening that partitions the emission area. The light blocking pattern BM may be disposed in the non-emission area, and may not be disposed in the emission area. The light blocking pattern BM may include an inorganic material or an organic material including a light blocking material having a black color.

The color filter CF may be disposed in the opening defined by the light blocking pattern BM. The color filter CF may overlap the light-emitting layer EML in a plan view. The color filter CF may be arranged in consideration of the color of light emitted by the light-emitting layer EML. For example, when the light-emitting layer EML emits red light, the color filter CF may be a red color filter that transmits red light and blocks green light and blue light. For example, when the light-emitting layer EML emits green light, the color filter CF may be a green color filter that transmits green light and blocks red light and blue light. For example, when the light-emitting layer EML emits blue light, the color filter CF may be a blue color filter that transmits blue light and blocks red light and green light.

In an embodiment, as illustrated in FIG. 4, adjacent color filters CF may overlap in the non-emission area. A portion where the adjacent color filters CF overlap in the non-emission area may block light. However, the present disclosure is not necessarily limited thereto, and the color filters CF may not overlap in the non-emission area.

The flattening layer OC may be disposed on the color filter CF. The flattening layer OC may alleviate a step difference formed by the color filter CF. The flattening layer OC may include an inorganic insulating material and/or an organic insulating material.

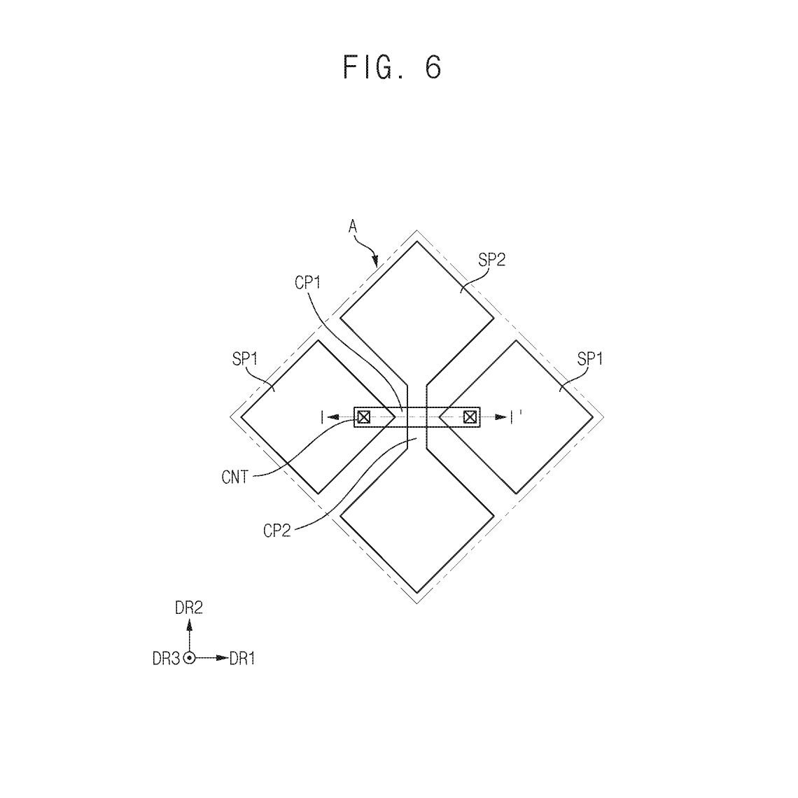

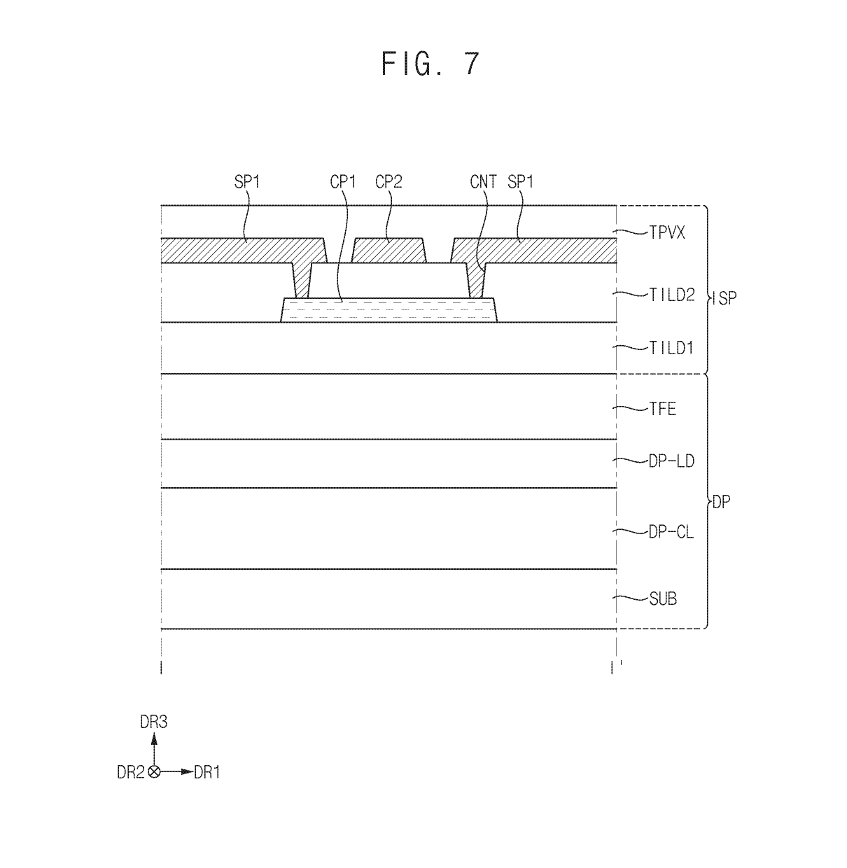

FIG. 5 is a plan view illustrating an example of an input sensing panel included in the display device of FIG. 3. FIG. 6 is an enlarged plan view of the area A of FIG. 5. FIG. 7 is a cross-sectional view taken along the line I-I` of FIG. 6.

Referring to FIGS. 5 and 6, the input sensing panel ISP may include a sensing area SA and a non-sensing area NSA. The sensing area SA may be an area that senses an external input. The sensing area SA may correspond to the display area DA of FIG. 2. The sensing area SA may have substantially the same area as the display area DA, or may have anarea greater than the area of the display area DA. The non-sensing area NSA may be positioned outside the sensing area SA. The non-sensing area NSA may surround at least a portion of the sensing area SA in a plan view. For example, the non-sensing area NSA may entirely surround the sensing area SA in a plan view. The non-sensing area NSA may correspond to the non-display area NDA of FIG. 2.

The input sensing panel ISP may include sensing electrodes IE, sensing lines TSL, and sensing pads IS-PD.

The sensing electrodes IE may sense the external input. The sensing electrodes IE may include first sensing electrodes IE1 and second sensing electrodes IE2. For example, in FIG. 5, the input sensing panel ISP is illustrated as including five first sensing electrodes IE1-1, IE1-2, IE1-3, IE1-4, and IE1-5 and four second sensing electrodes IE2-1, IE2-2, IE2-3, and IE2-4, but the present disclosure is not necessarily limited thereto. The number of the first sensing electrodes IE1 and the number of the second sensing electrodes IE2 may vary according to embodiments.

The sensing lines TSL may include first sensing lines TSL1 and second sensing lines TSL2. For example, in FIG. 5, five first sensing lines TSL1-1, TSL1-2, TSL1-3, TSL1-4, and TSL1-5) respectively connected to five first sensing electrodes IE1-1, IE1-2, IE1-3, IE1-4, and IE1-5) and four second sensing lines TSL2-1, TSL2-2, TSL2-3, and TSL2-4 respectively connected to four second sensing electrodes IE2-1, IE2-2, IE2-3, and IE2-4 are illustrated, but the present disclosure is not necessarily limited thereto.

The first sensing electrodes IE1 and the second sensing electrodes IE2 may be disposed in the sensing area SA, and the first sensing lines TSL1 and the second sensing lines TSL2 may be disposed in the non-sensing area NSA.

The first sensing electrodes IE1 may be arranged along the second direction DR2. Each of the first sensing electrodes IE1 may extend in the first direction DR1. Each of the first sensing electrodes IE1 may include first sensing portions SP1 and first connection portions CP1. Within one first sensing electrode IE1, the first sensing portions SP1 may be arranged along the first direction DR1. Each of the first connection portions CP1 may connect neighboring first sensing portions SP1.

The second sensing electrodes IE2 may be arranged along the first direction DR1. Each of the second sensing electrodes IE2 may extend in the second direction DR2. Each of the second sensing electrodes IE2 may include second sensing portions SP2 and second connection portions CP2. Within one second sensing electrode IE2, the second sensing portions SP2 may be arranged along the second direction DR2. Each of the second connection portions CP2 may connect neighboring second sensing portions SP2.

The first sensing electrodes IE1 and the second sensing electrodes IE2 may include a metal. For example, the first sensing electrodes IE1 and the second sensing electrodes IE2 may include aluminum (Al), titanium (Ti), copper (Cu), molybdenum (Mo), or the like.

Referring further to FIG. 7, the input sensing panel ISP may further include the first sensing insulating layer TILD1, the second sensing insulating layer TILD2, and the sensing protective layer TPVX.

The first connection portions CP1 may be disposed on the first sensing insulating layer TILD1. The second sensing insulating layer TILD2 may cover the first connection portions CP1. The first connection portions CP1 may correspond to the first sensing conductive pattern TMTL1 of FIG. 4.

The first sensing portions SP1 and the second connection portions CP2 may be disposed on the second sensing insulating layer TILD2. The first sensing portions SP1 may be connected to the first connection portion CP1 through a contact hole CNT. In addition, the second sensing portions SP2 may be disposed on the second sensing insulating layer TILD2. The sensing protective layer TPVX may cover the first sensing portions SP1, the second sensing portions SP2, and the second connection portions CP2. The first sensing portions SP1, the second sensing portions SP2, and the second connection portions CP2 may correspond to the second sensing conductive pattern TMTL2 of FIG. 4. However, the present disclosure is not necessarily limited thereto, and layers in which the first sensing portions SP1, the second sensing portions SP2, the first connection portions CP1, and the second connection portions CP2 are disposed may be variously changed.

As illustrated in FIG. 5, the first sensing lines TSL1 may be connected to an end of the first sensing electrodes IE1, respectively. The second sensing lines TSL2 may be connected to both ends of the second sensing electrodes IE2, respectively. However, the present disclosure is not necessarily limited thereto. For example, the first sensing lines TSL1 may be connected to both ends of the first sensing electrodes IE1, respectively, and the second sensing lines TSL2 may be connected to an end of the second sensing electrodes IE2, respectively.

The sensing pads IS-PD may overlap the dummy pads DP-DPD of the display panel DP of FIG. 2. Accordingly, the sensing pads IS-PD may be electrically connected to the dummy pads DP-DPD of the display panel DP.

A first end of each of the first sensing lines TSL1 may be connected to the first sensing electrode IE1, and a second end opposite to the first end of each of the first sensing lines TSL1 may be connected to the sensing pad IS-PD. That is, the first sensing lines TSL1 may electrically connect the sensing pad IS-PD and the first sensing electrode IE1.

A first end of each of the second sensing lines TSL2 may be connected to the second sensing electrode IE2, and a second end opposite to the first end of each of the second sensing lines TSL2 may be connected to the sensing pad IS-PD. That is, the second sensing lines TSL2 may electrically connect the sensing pad IS-PD and the second sensing electrode IE2.

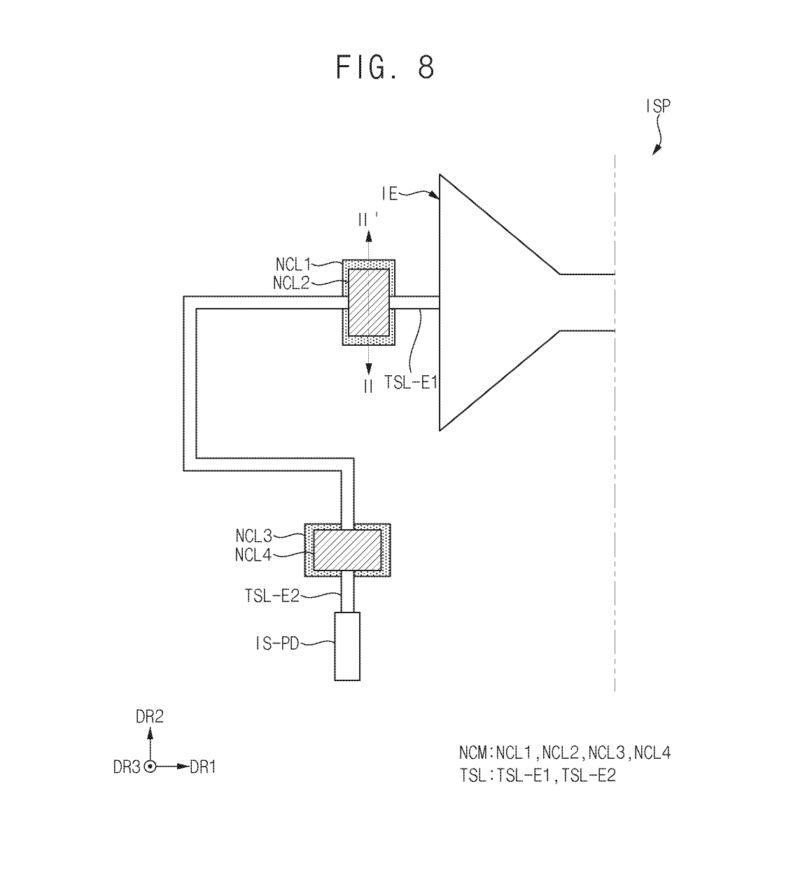

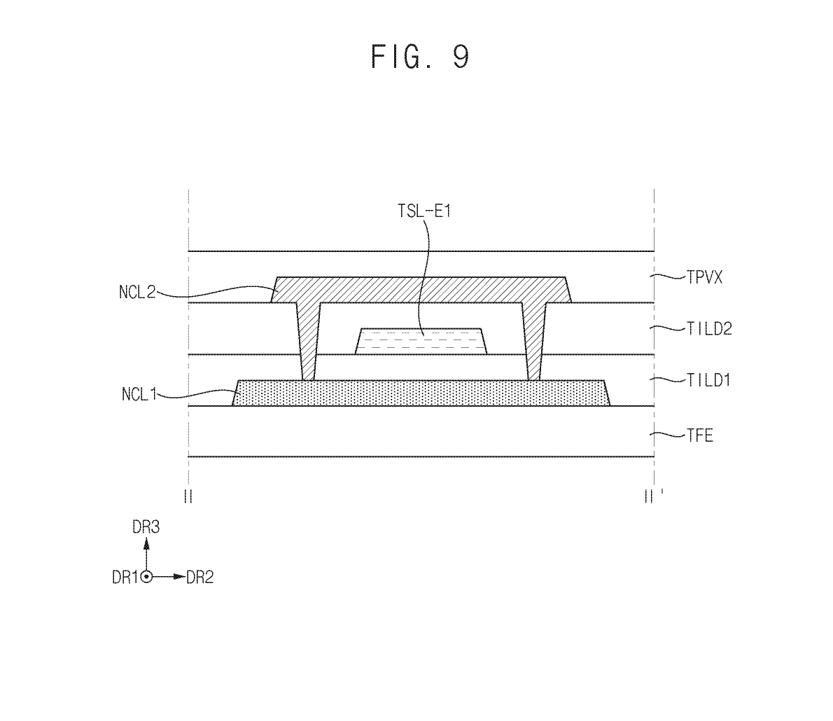

FIG. 8 is a plan view illustrating a sensing line and a noise reduction member included in the input sensing panel of FIG. 5. FIG. 9 is a cross-sectional view taken along the line II-II` of FIG. 8.

For example, FIG. 8 is a plan view that enlarges a portion of an area of the input sensing panel ISP of FIG. 5 to illustrate the connection relationship between the sensing line TSL and the sensing pad IS-PD and the connection relationship between the sensing line TSL and the sensing electrode IE. In FIG. 8, one sensing pad IS-PD, one sensing line TSL, and one sensing electrode IE are selectively illustrated. The arrangement relationship between a noise reduction member NCM and the sensing line TSL illustrated in FIG. 8 may be substantially the same in the first sensing line TSL1 and the second sensing line TSL2 of FIG. 5. Accordingly, for convenience of description, the first sensing line TSL1 and the second sensing line TSL2 are uniformly expressed as the sensing line TSL hereinafter.

Referring to FIGS. 8 and 9, the sensing line TSL may electrically connect the sensing pad IS-PD and the sensing electrode IE. In an embodiment, a first end TSL-E1 of the sensing line TSL may be connected to the sensing electrode IE, and a second end TSL-E2 opposite to the first end TSL-E1 of the sensing line TSL may be connected to the sensing pad IS-PD.

As illustrated in FIG. 8, the input sensing panel ISP may further include a noise reduction member NCM adjacent to or overlapping the first end TSL-E1 of the sensing line TSL and the second end TSL-E2 of the sensing line TSL in a plan view.

In an embodiment, the noise reduction member NCM adjacent to or overlapping the first end TSL-E1 of the sensing line TSL in a plan view may include a first noise reduction pattern NCL1 and a second noise reduction pattern NCL2. The first noise reduction pattern NCL1 and the second noise reduction pattern NCL2 may surround at least a portion of the sensing line TSL. For example, the first noise reduction pattern NCL1 and the second noise reduction pattern NCL2 may surround the first end TSL-E1 of the sensing line TSL or a portion adjacent to the first end TSL-E1. The first noise reduction pattern NCL1 and the second noise reduction pattern NCL2 may be shielding layers configured to shield the sensing line TSL from capacitive and/or electromagnetic interference.

In an embodiment, the noise reduction member NCM adjacent to or overlapping the second end TSL-E2 of the sensing line TSL in a plan view may include a third noise reduction pattern NCL3 and a fourth noise reduction pattern NCL4. The third noise reduction pattern NCL3 and the fourth noise reduction pattern NCL4 may surround at least a portion of the sensing line TSL. For example, the third noise reduction pattern NCL3 and the fourth noise reduction pattern NCL4 may surround the second end TSL-E2 of the sensing line TSL or a portion adjacent to the second end TSL-E2.

The noise reduction member NCM adjacent to or overlapping the first end TSL-E1 of the sensing line TSL in a plan view and the noise reduction member NCM adjacent to or overlapping the second end TSL-E2 of the sensing line TSL in a plan view may have structures that are substantially identical or symmetrical to each other. In other words, the first noise reduction pattern NCL1 adjacent to or overlapping the first end TSL-E1 in a plan view may have a substantially identical or symmetrical structure to the third noise reduction pattern NCL3 adjacent to or overlapping the second end TSL-E2 in a plan view. In addition, the second noise reduction pattern NCL2 adjacent to or overlapping the first end TSL-E1 in a plan view may have a substantially identical or symmetrical structure to the fourth noise reduction pattern NCL4 adjacent to or overlapping the second end TSL-E2 in a plan view. In some embodiments of the disclosure, the first noise reduction pattern NCL1 and/or the second noise reduction pattern NCL2, when described as being "adjacent to" another element, may be understood to lie within a predetermined distance from that element, wherein the predetermined distance may be up to 2mm.

Accordingly, hereinafter, the following descriptions will focus on the noise reduction member NCM adjacent to or overlapping the first end TSL-E1 of the sensing line TSL in a plan view, that is, the first noise reduction pattern NCL1 and the second noise reduction pattern NCL2 adjacent to or overlapping the first end TSL-E1 in a plan view. The descriptions of the first noise reduction pattern NCL1 can be equally applied to the third noise reduction pattern NCL3. The descriptions of the second noise reduction pattern NCL2 can be equally applied to the fourth noise reduction pattern NCL4.

As illustrated in FIG. 9, the first noise reduction pattern NCL1 may be disposed on the encapsulation layer TFE. The first noise reduction pattern NCL1 may be disposed between the encapsulation layer TFE and the sensing line TSL. The first sensing insulating layer TILD1 may cover the first noise reduction pattern NCL1 on the encapsulation layer TFE. In an embodiment, the first noise reduction pattern NCL1 may be disposed under the sensing electrode IE. For example, the first noise reduction pattern NCL1 may be disposed on an upper surface of the encapsulation layer TFE, and the sensing electrode IE may be disposed on an upper surface of the first sensing insulating layer TILD1 or an upper surface of the second sensing insulating layer TILD2.

The first end TSL-E1 of the sensing line TSL may be disposed on the first sensing insulating layer TILD1. The second sensing insulating layer TILD2 may cover the first end TSL-E1 of the sensing line TSL on the first sensing insulating layer TILD1.

The second noise reduction pattern NCL2 may be disposed on the sensing line TSL. For example, the second noise reduction pattern NCL2 may be disposed on the second sensing insulating layer TILD2. The second noise reduction pattern NCL2 may be connected to the first noise reduction pattern NCL1 through a contact hole penetrating the first sensing insulating layer TILD1 and the second sensing insulating layer TILD2. The sensing protective layer TPVX may cover the second noise reduction pattern NCL2 on the second sensing insulating layer TILD2.

In an embodiment, as illustrated in FIG. 8, a first area in which the first noise reduction pattern NCL1 is disposed may be greater than a second area in which the second noise reduction pattern NCL2 is disposed in a plan view, but the present disclosure is not necessarily limited thereto.

The first noise reduction pattern NCL1 and the second noise reduction pattern NCL2 may reduce noise applied to the sensing line TSL. For example, the noise may be caused by interference between the input sensing panel ISP and the display panel (DP, see FIG. 4).

In an embodiment, the first noise reduction pattern NCL1 and the second noise reduction pattern NCL2 may include a magnetic material. For example, the first noise reduction pattern NCL1 and the second noise reduction pattern NCL2 may include a manganese-zinc (Mn-Zn) ferrite or a nickel-zinc (Ni-Zn) ferrite. However, the present disclosure is not necessarily limited thereto, and the first noise reduction pattern NCL1 and the second noise reduction pattern NCL2 may include a nanocrystal. In this case, the first noise reduction pattern NCL1 and the second noise reduction pattern NCL2 may have high permeability. In this case, when a current including noise (e.g., a high-frequency signal) flows in the sensing line TSL, an induced magnetic field may be formed inside the first noise reduction pattern NCL1 and inside the second noise reduction pattern NCL2 due to a change in the current, and the noise may be reduced by the induced magnetic field. As the noise is reduced, the reliability of the input sensing panel ISP that senses the external input may be improved.

In an embodiment, the first noise reduction pattern NCL1 and the second noise reduction pattern NCL2 may include the same magnetic material as each other. For example, the first noise reduction pattern NCL1 and the second noise reduction pattern NCL2 may include the same ferrite (e.g., a nickel-zinc ferrite) as each other. However, the present disclosure is not necessarily limited thereto, and the first noise reduction pattern NCL1 and the second noise reduction pattern NCL2 may include different magnetic materials.

In an embodiment, the first noise reduction pattern NCL1 and the second noise reduction pattern NCL2 may include a metal. For example, the first noise reduction pattern NCL1 and the second noise reduction pattern NCL2 may include copper (Cu), aluminum (Al), or the like, but the present disclosure is not necessarily limited thereto. In this case, the first noise reduction pattern NCL1 and the second noise reduction pattern NCL2 may shield the noise. Accordingly, the reliability of the input sensing panel ISP that senses the external input may be improved. In an embodiment, the first noise reduction pattern NCL1 and the second noise reduction pattern NCL2 may be in a floating state. That is, the first noise reduction pattern NCL1 and the second noise reduction pattern NCL2 may be electrically isolated from other electrodes and other lines and may be not connected to a fixed voltage or ground to maintain a floating state. The first noise reduction pattern NCL1 and the second noise reduction pattern NCL2 in the floating state may act as capacitive shields and may provide noise reduction benefits due to capacitive coupling.

In an embodiment, the first noise reduction pattern NCL1 and the second noise reduction pattern NCL2 may include the same metal as each other. However, the present disclosure is not necessarily limited thereto, and the first noise reduction pattern NCL1 and the second noise reduction pattern NCL2 may include different metals.

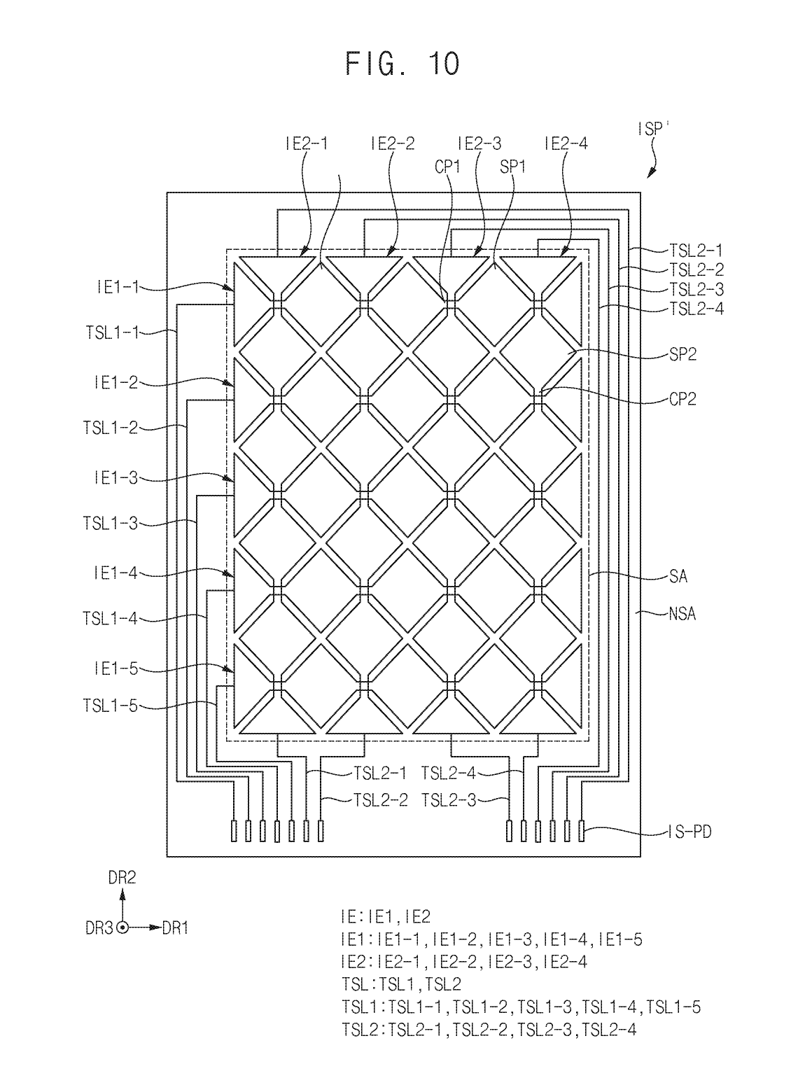

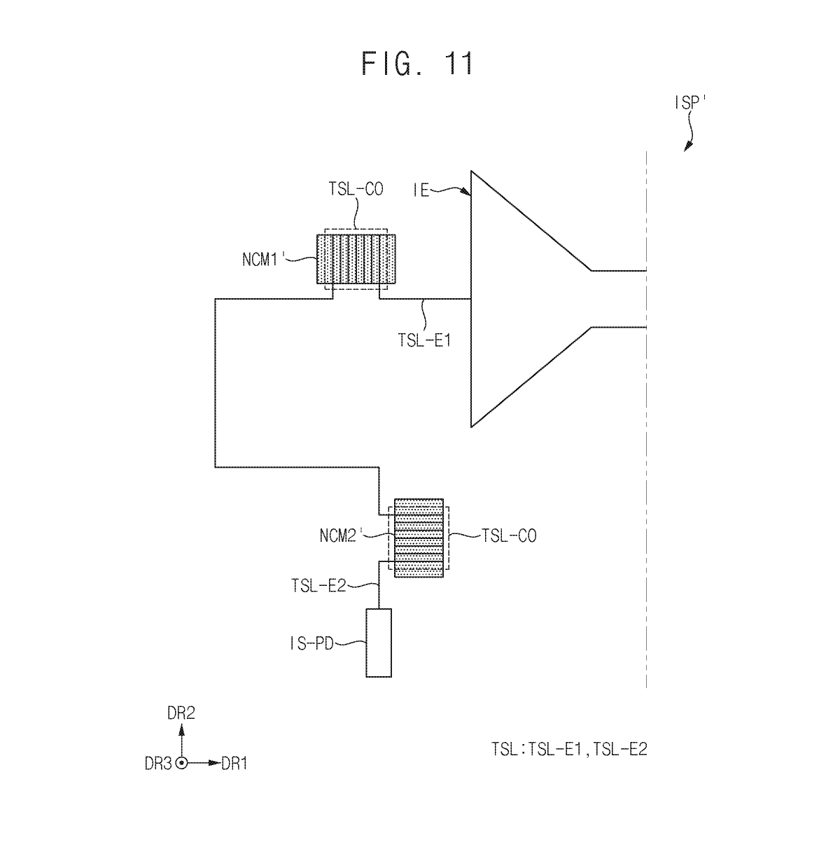

FIG. 10 is a plan view illustrating another example of an input sensing panel included in the display device of FIG. 3. FIG. 11 is a plan view illustrating a sensing line and a noise reduction member included in the input sensing panel of FIG. 10.

Referring to FIGS. 10 and 11, the input sensing panel ISP` may include the sensing electrodes IE, the sensing lines TSL, the sensing pads IS-PD, and a noise reduction member. The noise reduction member may include a first noise reduction member NCM1` and a second noise reduction member NCM2`.

The input sensing panel ISP` may be substantially the same as the input sensing panel ISP described above with reference to FIGS. 5 to 7, except for the arrangement relationship between the noise reduction member and the sensing line TSL. Hereinafter, redundant descriptions of the input sensing panel ISP described above with reference to FIGS. 5 to 7 are omitted or summarized.

As illustrated in FIG. 11, the sensing line TSL may be disposed between the sensing pad IS-PD and the sensing electrode IE. In an embodiment, a first end TSL-E1 of the sensing line TSL may be connected to the sensing electrode IE, and a second end TSL-E2 opposite to the first end TSL-E1 of the sensing line TSL may be connected to the sensing pad IS-PD.

The first noise reduction member NCM1` may be adjacent to or overlap the first end TSL-E1 of the sensing line TSL. In an embodiment, the sensing line TSL may include a coil portion TSL-CO having a coil shape that surrounds the first noise reduction member NCM1` at the first end TSL-E1 or at a portion adjacent to the first end TSL-E1.

The second noise reduction member NCM2` may be adjacent to or overlap the second end TSL-E2 of the sensing line TSL. The second noise reduction member NCM2` may be spaced apart from the first noise reduction member NCM1`. In an embodiment, the sensing line TSL may include a coil portion TSL-CO having a coil shape that surrounds the second noise reduction member NCM2` at the second end TSL-E2 or at a portion adjacent to the second end TSL-E2.

For example, the first noise reduction member NCM1` and the second noise reduction member NCM2` may have a cylindrical shape.

The first noise reduction member NCM1` and the second noise reduction member NCM2` may include a magnetic material, such as a manganese-zinc (Mn-Zn) ferrite or a nickel-zinc (Ni-Zn) ferrite. The first noise reduction member NCM1` and the second noise reduction member NCM2` may have high permeability. When a current containing noise, such as electromagnetic interference or a high frequency signal, flows in the sensing line TSL, an induced magnetic field may be formed inside the first noise reduction member NCM1` and the second noise reduction member NCM2` due to a change in the current. This induced magnetic field may attenuate the noise component of the current. As a result, the reliability of the input sensing panel ISP` that senses the external input may be improved.

FIG. 12 is a block diagram illustrating an electronic device according to an embodiment of the present disclosure.

Referring to FIG. 12, an electronic device 10 according to an embodiment may include a display module 11, a processor 12, a memory 13, and a power module 14. The display device according to an embodiment may be applied to a variety of electronic devices. The electronic device 10 according to an embodiment may include the display device described above, and may further include modules or devices having other additional functions in addition to the display device. For example, the display module 11 may correspond to the display module DM of FIGS. 3 and 4.

The processor 12 may include at least one of a central processing unit (CPU), an application processor (AP), a graphic processing unit (GPU), a communication processor (CP), an image signal processor (ISP), and a controller.

The memory 13 may store data information required for operation of the processor 12 or the display module 11. When the processor 12 executes an application stored in the memory 13, an image data signal and/or an input control signal may be transmitted to the display module 11, and the display module 11 may process the received signals and may output image information through a display screen.

The power module 14 may include a power supply module, such as a power adapter or a battery device, etc., and a power conversion module that converts power supplied by the power supply module to generate the power required for operation of the electronic device 10. That is, the power module 14 may provide power to the display device according to the embodiments described above.

At least one of the components of the electronic device 10 described above may be included in the display device according to the embodiments described above. In addition, some of the individual modules that are functionally included in one module may be included in the display device and others may be provided separately from the display device. For example, the display device may include the display module 11, and the processor 12, the memory 13, and the power module 14 may be provided in the form of other devices in the electronic device 10 other than the display device.

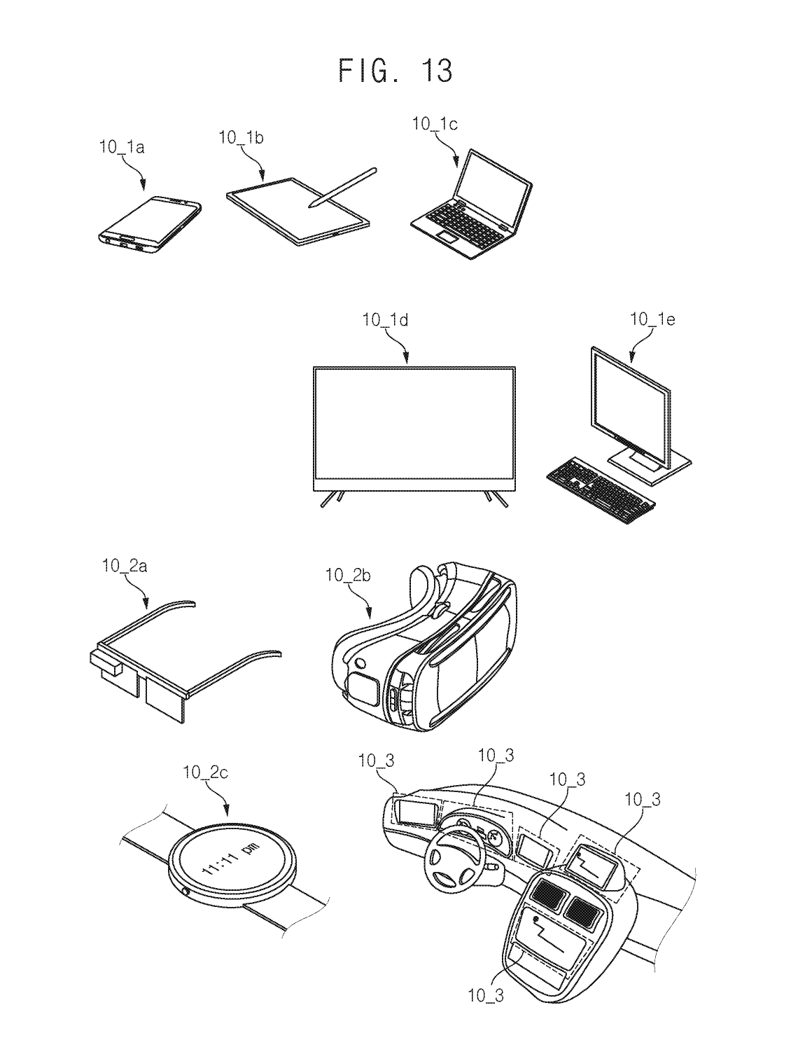

FIG. 13 is a schematic view of an electronic device according to various embodiments.

Referring to FIG. 13, various electronic devices to which a display device according to the embodiments is applied may include image display electronic devices such as a smartphones 10_1a, a tablet PC 10_1b, a laptop 10_1c, a television 10_1d, a desk monitor 10_1e, or the like, wearable electronic devices including display modules such as a smart glasses 10_2a, a head-mounted display 10_2b, and a smart watch 10_2c, or the like, and vehicle electronic devices 10_3 including display modules such as a CID (center information display) which may be disposed on a instrument panel, a center fascia, and a dashboard of an automobile and a room mirror display, or the like.

The present disclosure may be applied to various display devices. For example, the present disclosure is applicable to various display devices such as display devices for vehicles, ships and aircraft, portable communication devices, display devices for exhibition or information transmission, medical display devices, and the like.

According to one or more embodiments, a display device may include: a substrate; a light-emitting element layer on the substrate and including a light-emitting element; an encapsulation layer on the light-emitting element layer and covering the light-emitting element; a sensing electrode on the encapsulation layer; a sensing line on the encapsulation layer and including a first end connected to the sensing electrode; a first noise reduction pattern between the encapsulation layer and the sensing line, overlapping or within a predetermined distance from the first end in a plan view, and configured to reduce noise applied to the sensing line; and a second noise reduction pattern on the sensing line, overlapping or within the predetermined distance from the first end in the plan view, configured to reduce the noise applied to the sensing line, and connected to the first noise reduction pattern.

The first noise reduction pattern and the second noise reduction pattern may surround at least a portion of the sensing line.

Each of the first noise reduction pattern and the second noise reduction pattern may include a magnetic material.

Each of the first noise reduction pattern and the second noise reduction pattern may include a manganese-zinc ferrite or a nickel-zinc ferrite.

Each of the first noise reduction pattern and the second noise reduction pattern may include a metal.

The first noise reduction pattern and the second noise reduction pattern may be in a floating state.

The first noise reduction pattern and the second noise reduction pattern may include a same material.

The first noise reduction pattern and the second noise reduction pattern may include different materials.

In the plan view, a first area in which the first noise reduction pattern is disposed may be greater than a second area in which the second noise reduction pattern is disposed.

The display device may further include: a first sensing insulating layer on the encapsulation layer and covering the first noise reduction pattern; a second sensing insulating layer on the first sensing insulating layer and covering the first end; and a sensing protective layer on the second sensing insulating layer and covering the second noise reduction pattern.

The first noise reduction pattern may be under the sensing electrode.

The display device may further include: a sensing pad on the substrate and connected to the sensing electrode, wherein the sensing line may further include a second end which is opposite to the first end and may be connected to the sensing pad.

The display device may further include: a third noise reduction pattern between the encapsulation layer and the sensing line, and overlapping or within the predetermined distance from the second end in the plan view; and a fourth noise reduction pattern on the sensing line, overlapping or within the predetermined distance from the second end in the plan view, and connected to the third noise reduction pattern.

The third noise reduction pattern and the fourth noise reduction pattern may surround at least a portion of the sensing line.

The sensing electrode may include: a first sensing electrode extending in a first direction; and a second sensing electrode extending in a second direction intersecting the first direction.

According to one or more embodiments, a display device may include: a substrate; a light-emitting element layer on the substrate and including a light-emitting element; an encapsulation layer on the light-emitting element layer and covering the light-emitting element; a sensing electrode on the encapsulation layer; a first noise reduction member on the encapsulation layer and including a magnetic material; and a sensing line on the encapsulation layer, the sensing line including a first end connected to the sensing electrode and surrounding the first noise reduction member at the first end.

The first noise reduction member may include: a manganese-zinc ferrite or a nickel-zinc ferrite.

The display device may further include: a sensing pad on the substrate and connected to the sensing electrode, wherein the sensing line may further include a second end which is opposite to the first end and may be connected to the sensing pad.

The display device may further include: a second noise reduction member on the encapsulation layer, including the magnetic material, and spaced apart from the first noise reduction member, wherein the sensing line has a coil shape surrounding the second noise reduction member at the second end.

According to one or more embodiments, an electronic device may include: a display panel including a substrate, a light-emitting element on the substrate, and an encapsulation layer on the light-emitting element and covering the light-emitting element; an input sensing panel on the display panel; and a processor configured to transmit an image data signal and an input control signal to the display panel. The input sensing panel may include: a sensing electrode on the encapsulation layer; a sensing line on the encapsulation layer and including a first end connected to the sensing electrode; a first noise reduction pattern between the encapsulation layer and the sensing line, overlapping or within a predetermined distance from the first end in a plan view, and configured to reduce noise applied to the sensing line; and a second noise reduction pattern on the sensing line, overlapping or within the predetermined distance from the first end in the plan view, configured to reduce the noise applied to the sensing line, and connected to the first noise reduction pattern.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A display device comprising:
a substrate;
a light-emitting element layer on the substrate and comprising a light-emitting element;
an encapsulation layer on the light-emitting element layer and covering the light-emitting element;
a sensing electrode on the encapsulation layer;
a sensing line on the encapsulation layer and comprising a first end connected to the sensing electrode;
a first noise reduction pattern between the encapsulation layer and the sensing line, overlapping or within a predetermined distance from the first end in a plan view, and configured to reduce noise applied to the sensing line; and
a second noise reduction pattern on the sensing line, overlapping or within the predetermined distance from the first end in the plan view, configured to reduce the noise applied to the sensing line, and connected to the first noise reduction pattern.

2. The display device of claim 1, wherein the first noise reduction pattern and the second noise reduction pattern surround at least a portion of the sensing line.

3. The display device of claim 1, wherein each of the first noise reduction pattern and the second noise reduction pattern comprises a magnetic material.

4. The display device of claim 3, wherein each of the first noise reduction pattern and the second noise reduction pattern comprises a manganese-zinc ferrite or a nickel-zinc ferrite.

5. The display device of claim 1, wherein each of the first noise reduction pattern and the second noise reduction pattern comprises a metal.

6. The display device of claim 5, wherein the first noise reduction pattern and the second noise reduction pattern are in a floating state.

7. The display device of claim 1, wherein the first noise reduction pattern and the second noise reduction pattern include a same material.

8. The display device of claim 1, wherein the first noise reduction pattern and the second noise reduction pattern include different materials.

9. The display device of claim 1, wherein in the plan view, a first area in which the first noise reduction pattern is disposed is greater than a second area in which the second noise reduction pattern is disposed.

10. The display device of claim 1, further comprising:
a first sensing insulating layer on the encapsulation layer and covering the first noise reduction pattern;
a second sensing insulating layer on the first sensing insulating layer and covering the first end; and
a sensing protective layer on the second sensing insulating layer and covering the second noise reduction pattern.

11. The display device of claim 1, wherein the first noise reduction pattern is under the sensing electrode.

12. The display device of claim 1, further comprising:
a sensing pad on the substrate and connected to the sensing electrode,
wherein the sensing line further comprises a second end which is opposite to the first end and is connected to the sensing pad.

13. The display device of claim 12, further comprising:
a third noise reduction pattern between the encapsulation layer and the sensing line, and overlapping or within the predetermined distance from the second end in the plan view; and
a fourth noise reduction pattern on the sensing line, overlapping or within the predetermined distance from the second end in the plan view, and connected to the third noise reduction pattern.

14. The display device of claim 13, wherein the third noise reduction pattern and the fourth noise reduction pattern surround at least a portion of the sensing line.

15. The display device of claim 1, wherein the sensing electrode comprises:
a first sensing electrode extending in a first direction; and
a second sensing electrode extending in a second direction intersecting the first direction.

16. A display device comprising:
a substrate;
a light-emitting element layer on the substrate and comprising a light-emitting element;
an encapsulation layer on the light-emitting element layer and covering the light-emitting element;
a sensing electrode on the encapsulation layer;
a first noise reduction member on the encapsulation layer and comprising a magnetic material; and
a sensing line on the encapsulation layer, the sensing line comprising a first end connected to the sensing electrode, having a coil shape, and surrounding the first noise reduction member at the first end.

17. The display device of claim 16, wherein the first noise reduction member comprises a manganese-zinc ferrite or a nickel-zinc ferrite.

18. The display device of claim 16, further comprising:
a sensing pad on the substrate and connected to the sensing electrode,
wherein the sensing line further comprises a second end which is opposite to the first end and is connected to the sensing pad.

19. The display device of claim 18, further comprising:
a second noise reduction member on the encapsulation layer, comprising the magnetic material, and spaced apart from the first noise reduction member,
wherein the sensing line has a coil shape surrounding the second noise reduction member at the second end.

20. An electronic device comprising:
a display panel comprising a substrate, a light-emitting element on the substrate, and an encapsulation layer on the light-emitting element and covering the light-emitting element;
an input sensing panel on the display panel; and
a processor configured to transmit an image data signal and an input control signal to the display panel,
wherein the input sensing panel comprises:
a sensing electrode on the encapsulation layer;
a sensing line on the encapsulation layer and comprising a first end connected to the sensing electrode;
a first noise reduction pattern between the encapsulation layer and the sensing line, overlapping or within a predetermined distance from the first end in a plan view, and configured to reduce noise applied to the sensing line; and
a second noise reduction pattern on the sensing line, overlapping or within the predetermined distance from the first end in the plan view, configured to reduce the noise applied to the sensing line, and connected to the first noise reduction pattern.
